(19) United States
(12) Patent Application Publication
(10) Pub. No.: US 2009/0276680 A1
(43) Pub. Date: Nov. 5, 2009

(54) ERROR CORRECTION CIRCUIT AND METHOD THEREOF

(76) Inventor: Yen-Lung CHIU, Taipei (TW)

Correspondence Address: BIRCH STEWART KOLASCH & BIRCH, PO BOX 747, FALLS CHURCH, VA, 22040-0747, US

(21) Appl. No.: 12/351,989

(22) Filed: Jan. 12, 2009

(30) Foreign Application Priority Data
Apr. 30, 2008 (CN) 200810096068.9

(51) Int. Cl. H03M 13/05; G06F 11/10

(52) U.S. Cl. 714/752; 714/E11.032

(57) ABSTRACT

An error correction method is applicable for accessing a data in a storage medium. The method includes the steps of: encoding a portion of the data and the whole data to produce a partial data parity for that portion of the data and a whole data parity for the whole data; using the partial data parity to decode the corresponding portion of the data and the corresponding partial data parity in order to correct error bits from the corresponding portion of the data and from the partial data parity according to the decoded result; using the whole data parity to decode the whole data and the whole data parity in order to correct the error bit from the whole data and the whole data parity according to the decoded result; and outputting the corrected data.

### BACKGROUND OF THE INVENTION

1. Field of the Invention

The present invention relates to an error correction circuit and an error correction method for a storage medium, and more particularly to an error correction circuit and a method thereof for improving the error correction capability regarding a data stream of a storage medium.

2. Description of Related Art

As science and technologies advance, many operating procedures employ digital processing, and manufacturers put up tremendous efforts to develop and produce high-capacity compact storage media for storing a large quantity of data at a lower cost, and to meet with the requirements of the market.

However, external interferences or noises occurred during the process of transmitting data between storage media may cause errors in data. For example, values of a plurality of bits in a data are changed by the interferences or noises while undergoing the process of being stored in a flash memory of an electronic product, therefore the incorrect data will be obtained when users read the data from the memory. To solve this problem, an error correcting code technique that using a parity produced by computing the data can achieve the effects of detecting and correcting the error bit of the data has developed.

Referring to FIG. 1 for a schematic view of an embodiment which uses an error correcting code to process a data stream in accordance with a prior art, a conventional error correcting code method, such as a BCH Code algorithm (BCH: Bose-Chaudhuri-Hocquenghem, which are the inventors' last names), divides a data stream to be stored in a memory into a plurality of data segments with a fixed length. In FIG. 1, the data stream is divided into N+1 data segments A₀, A₁, . . . , A_{N}, wherein the length of each data segment is equal to k-bit, and (n-k)-bit length of parities A₀^{#}, A₁^{#}, . . . , A_{N}^{#} are produced after the error correcting code is used to compute the data, wherein each data segment Aᵢ will add its corresponding parity Aᵢ^{#} to form a n-bit codeword. If it is necessary to read the data stream from the storage medium, the first codeword will be read first for the decoding procedure. In other words, the parity A0# is used for correcting the data segment A0, and then the decoding procedure is repeated for every subsequent codeword, and finally the corrected data segments A₀, A₁, . . . , A_{N} are combined into a data stream for the output.

The conventional BCH Code error correcting code algorithm is designed to have an error correction capability of t bits. In other words, at most t error bits (including the bits of the parity Aᵢ^{#} and the data segment Aᵢ) in each codeword can be corrected by using the parity, wherein the value of t is well known by those ordinarily skilled in the art, and thus will not be described here.

Even though the error correcting code can solve the aforementioned problem to a certain extend, but a high error rate per unit volume is still problematic, wherein the problem is even more apparent as the semiconductor fabrication process technology advances continuously and the capacity of a storage medium per unit volume expands increasingly. Therefore, finding a way of improving the error correction capability without incurring a higher level of complexity of the hardware or a higher manufacturing cost and implementing a simple and easy hardware and software error correction capability is a technical field worth researching.

### SUMMARY OF THE INVENTION

In view of the foregoing shortcomings of the prior art, the present invention provides an error correction method that encodes a portion of a data segment to produce a partial data parity, and produces a whole data parity after the whole data segment is encoded. In other words, the whole data parity is the parity of the whole data; the partial data parity is the parity of a portion of the data, and the number of partial data parity depends on the number of portions of the data. Since the partial data parity and the whole data parity has equal error correction capability, assuming one whole parity and one partial parity is applied, then the overall error correction capability can be improved by two times via simply correcting each portion of data segment without increasing the complexity of hardware and software.

It is a primary objective of the present invention to provide an error correction method for improving the error correction capability regarding a data stream.

The present invention discloses an error correction encoding circuit comprising a shift registers and a plurality of auxiliary shift registers, and it is applied for error correction code encoding while writing data to a storage medium. The shift registers are provided for receiving the data stream and applied by the encoder to encode the parity of the data segment (a.k.a. whole data segment), and the auxiliary shift registers are provided for preserving the parity bits encoded from the front partial data segment. The decoding circuit of the storage medium uses the whole data parity and the partial data parity to correct the data stream.

The present invention also discloses an error correction method applicable in a storage medium for accessing data and comprising the following steps:

Firstly, an encoding procedure is performed when it is necessary to store a data in a storage medium, and a portion of the data and the whole data are encoded to produce a partial data parity for the portion of the data and a whole data parity for the whole data respectively. Secondly, a decoding procedure is performed when it is necessary to read the data from the storage medium, and the decoding procedure comprises the steps of: correcting error bits of both of the front portion of the data and the corresponding parity by applying the partial data parity; correcting error bits of both of the whole data (including the corrected portion of the data in the first step) and the corresponding parity by applying the whole data parity; and outputting the corrected data. To be more specific, “correcting error bits of both of the whole data (including the corrected portion of the data in the first step) and the corresponding parity by applying the whole data parity”, is especially important and different from prior art. Where prior art only has whole parity on each segment data (i.e. A₀^{#} corrects A₀, A₁^{#} correct A₁ . . . A_{N}^{#} corrects A_{N}, then combine the data segments, as in FIG. 1, therefore A₀ can only have t number of errors), the present invention reinforce the correction capability by introducing the partial data parity for correcting a portion of data before decoding the whole codeword. (i.e. assume A₀ is encoded and split into {a₀₀,a₀₁,a₀₀^{#},A₀^{#}}, so that A₀ is split into two portions of the data segment a₀₀ and a₀₁, and encoded with a partial data parity a₀₀^{#}, and a whole data parity A₀^{#}. Therefore a₀₀^{#} corrects a₀₀, and A₀^{#} corrects a₀₀ and a₀₁). Therein, if there are t error bits in a₀₀+a₀₀^{#}, then a₀₀^{#} will be applied to remove the t error bits, and then if there remains t error bits in a₀₁+A₀^{#}, then-A₀^{#} will be applied to remove the remain t error bits, therefore this method can correct up to t+t errors under the condition that each portion of data contains no more than t error bits. Similarly, subsequent segments A₁, A₂ . . . A_{N} will also be divided into portions to allow for this reinforcement correction.

In a preferred embodiment of the present invention, the error correction method is applicable for accessing an original data stream in a storage medium. Before the encoding procedure takes place, the original data stream is divided into at least one data segment with an equal length, wherein the data segment is the aforementioned data of the last paragraph. The data segment is processed according to the encoding/decoding method disclosed by the present invention. After the decoding procedure is completed, all corrected data segments are combined sequentially into the original data stream for output.

In a preferred embodiment of the present invention, the encoding procedure further comprises the step of storing a portion of the data, a partial parity, the data and a whole parity into the storage medium.

In a preferred embodiment of the present invention, the encoding procedure and the decoding procedure adopt a Bose-Chaudhuri-Hocquenghem Code (BCH Code) algorithm, a Reed-Solomon Code (RS Code) algorithm or any cyclic code.

In a preferred embodiment of the present invention, a plurality of registers are provided for temporarily storing a partial parity produced after a portion of the data is computed, and a program is used for producing the partial parity after the portion of the data is computed.

In a preferred embodiment of the present invention, the error correction capability is directly proportional to the number of partial parities of the divided portion of the data.

In addition to the general description above, preferred embodiments together with related drawings are provided for illustrating the method, technical measure and performance of the present invention that achieve the expected objectives, and other objectives and advantages of the present invention will be described as follows.

### BRIEF DESCRIPTION OF THE DRAWINGS

FIG. 1 is a schematic view of an embodiment of using an error correcting code to process a data stream in accordance with a prior art;

FIG. 2 is a schematic view of a circuit structure of an error correcting code in accordance with a preferred embodiment of the present invention;

FIG. 3A is a schematic view of a data segment storage format in accordance with a preferred embodiment of the present invention;

FIG. 3B is a schematic view of a data segment storage format in accordance with another preferred embodiment of the present invention;

FIG. 3C is a schematic view of a data segment storage format's data process in accordance with a preferred embodiment of the present invention; and

FIG. 4 is a flow chart of an error correction method in accordance with the present invention.

FIG. 5A is another schematic view of a data segment storage format in accordance with a preferred embodiment of the present invention;

FIG. 5B is another schematic view of a data segment storage format in accordance with another preferred embodiment of the present invention;

FIG. 5C is another schematic view of a data segment storage format's data process in accordance with a preferred embodiment of the present invention; and

FIG. 6-1˜6-3 is another flow chart of an error correction method in accordance with the present invention.

### DETAILED DESCRIPTION OF PREFERRED EMBODIMENTS

The present invention provides an error correction method comprising the steps of: dividing a data into a plurality of data segments and encoding a portion of the data segment and the whole data segment to produce a partial data segment parity (also called partial data parity hereafter) and a whole data segment parity (also called whole data parity hereafter) respectively; in other words, the whole data segment parity is the parity of the whole data segment; the partial data segment parity is the parity of a portion of the data segment, and the number of partial data segment parity depends on the number of portions of the data segment; and using the partial data segment parity and then the whole data segment parity to decode and to correct the corresponding data segments, so as to improve the error correction capability by multiple times through this reinforcing error correction method, which will not increase the complexity of hardware or software.

Although the present invention is characterized by an error correcting code circuit which is provided for processing data segments, and by the necessary hardware and sequences of operation required for accessing the data segments in a storage medium as described below. Those ordinarily skilled in the art can also use equivalent components and procedures to record the data segments into the storage medium and apply the present invention method to achieve the same result, thus the present invention is not limited to the embodiments disclosed here only.

In common error correcting code techniques (such as the BCH Code, which is used in the following embodiments for illustrating the present invention) generally use a cyclic parity to correct error bits, and the BCH Code defines a parameter (n, k, t), indicating that the length of an encoded data segment must be k bits for each time, and a parity of (n-k) bits will be produced after the BCH Code is computed, wherein each data segment will attach its corresponding parity to form a n-bit codeword. The BCH Code has a t-bit error correction capability; in other words, the parity can be applied to correct at most t error bits (including the error bits of the parity and the data segment) in each codeword. The operation of the aforementioned BCH Code is well known to those ordinarily skilled in the art, and thus will not be described here.

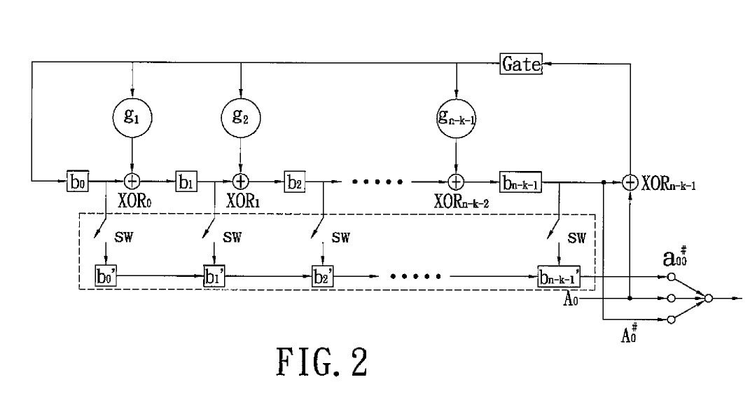

With reference to FIG. 2 for a schematic view of a circuit structure of an error correcting code in accordance with a preferred embodiment of the present invention. If it is necessary to record a raw data stream into a storage medium, the raw data stream is divided into a plurality of data segments for the data processing. For simplicity, a sequence of processing a first data segment A₀ (a.k.a. whole data segment A₀ which is one of plurality of data segments for the raw data stream, or simply data segment A₀) obtained from dividing the raw data stream is used for example. In FIG. 2, the circuit comprises (n-k) XOR gates (XOR₀, XOR₁, . . . , XORₙ₋ₖ₋₁), (n-k) shift registers (b₀, b₁, . . . , bₙ₋ₖ₋₁), and (n-k) auxiliary shift registers (b₀′, b₁′, . . . , bₙ₋ₖ₋₁′), wherein each register can store one bit of data, and the shift register bᵢ and the XOR gate XORᵢ are installed alternately with each other. Therein, the i regarding bᵢ and XORᵢ is a variable representing a number.

In a preferred embodiment, a portion of the data segment a₀₀ is defined as the content of the first half of the data segment A₀ (i.e. the first half of the data segment A₀ was also referred to as “front partial data segment” previously). When the partial data segment a₀₀ of the data segment A₀ has been serially inputted into the circuit, shift registers b₀, b₁, . . . , bₙ₋ₖ₋₁ will contain partial data parity. At this moment, partial data parity will be dumped into auxiliary shift registers b₀′, b₁′, . . . , bₙ₋ₖ₋₁′ and at the same time the remaining data segment a₀₁ of the data segment A₀ is subsequently inputted to the shift registers. After all data segment have been shifted into register b₀, b₁, . . . , bₙ₋ₖ₋₁, the registers shall contain the whole data parity A₀^{#}. In a preferred embodiment, (n-k) switches SW are added to the circuit, wherein the switches SW are coupled between the shift registers bᵢ and the auxiliary shift registers bᵢ′, when the partial data segment a₀₀ is serially input into the circuit, then electrically connect the switches SW (e.g. the switches SW are closed), so that the partial data segment a₀₀ is processed via the auxiliary shift registers b₀′, b₁′, . . . , bₙ₋ₖ₋₁′ to produce partial data parity a₀₀^{#}. By design, when the switches SW are not electrically connected (e.g. the switches SW are open), only the shift registers bᵢ are connected, therefore it is the shift registers bᵢ that receives the entire incoming data and outputs the whole data parity A₀^{#}. After the encoding is completed, the whole data parity A₀^{#} and the partial data parity a₀₀^{#} are appended to the data segment A₀ for an output.

In a preferred embodiment of the present invention, applying software method to the original hardware encode circuit without the auxiliary shift registers b₀′, b₁′, . . . , bₙ₋ₖ₋₁′ can also achieve the partial data parity a₀₀^{#}. Specifically, a program code provides a temporarily stored array variable for the decoding operation of temporarily storing the received data segment A₀, wherein the size of the temporarily stored array variable is the same as the size of the data segment A₀. During the encoding operation, the temporarily stored array variable will fill the first half of the array variable with a plurality of zeros (0s) and store the other half of the array variable with the first half data segment a₀₀ of the data segment A₀ to form a temporary data segment, and then the encoding operation is performed immediately on the temporary data segment to produce a parity a₀₀^{#} for the partial data segment. (also called a partial data parity a₀₀^{#}) Thereafter, the temporarily stored array variable receives the whole data segment A₀ to perform the encoding operation in order to produce a parity A₀^{#} for the whole data segment. (also called a whole data parity A₀^{#}) During the decoding operation, the partial data parity a₀₀^{#} is used for correcting the temporary data segment formed by combining the 0s and the first half data a₀₀ of the data segment A₀ first, and then using the whole data parity A₀^{#} to decode the corrected content of the partial data segment a₀₀ appended with the partial data segment a₀₁ of the second half. Thus, even the original hardware decoder of prior art applying the software method can be used for correcting up to two times of error bits under the condition that each portion of data contains no more than t error bits.

In a preferred embodiment of the present invention, the storage medium is a flash memory, an AND-flash memory, an OR-flash memory, a NAND-flash memory, a read only memory (ROM), an erasable read only memory (EROM), an electrically erasable read only memory (EEROM), an erasable programmable read only memory (EPROM) and an electrically erasable programmable read only memory (EEPROM), or a combination thereof.

In a preferred embodiment of the present invention, the error correcting code circuit for achieving the encoding procedure and the decoding procedure adopts a Bose-Chaudhuri-Hocquenghem Code (BCH Code) algorithm, a Reed-Solomon Code (RS Code) algorithm, or any cyclic code.

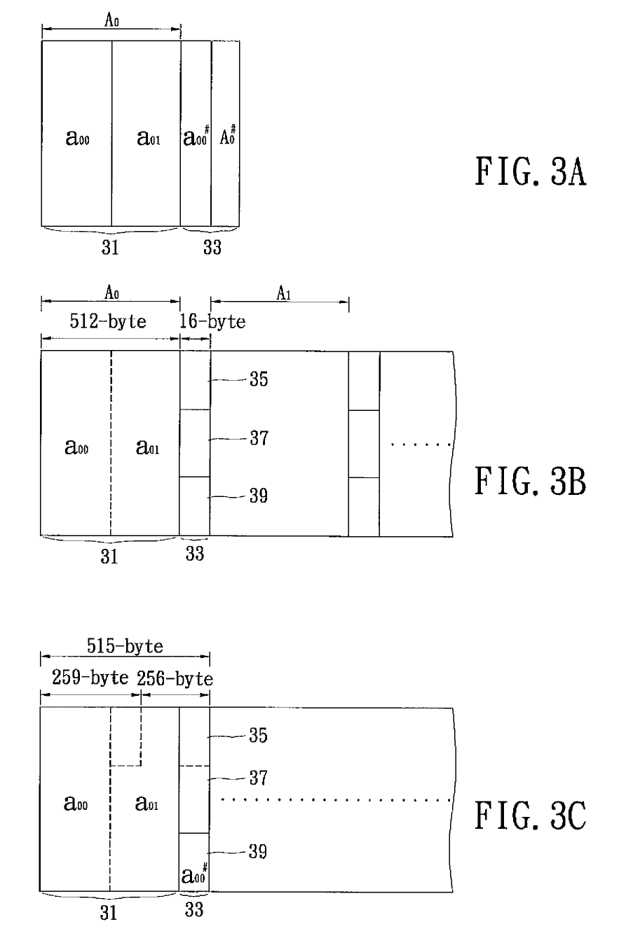

Please reference FIG. 3A for a schematic view of a data segment storage format in accordance with a preferred embodiment of the present invention, and view in conjunction with FIG. 2 for the related encoding circuit and its operation. A storage medium as shown in FIG. 3A provides the space of a data block 31 and a parity block 33 for each data segment to store the content of the data segment and the content of the parity respectively. After the data segment A₀ goes through the encoding process, the data segment A₀ (including a portion of the data segment a₀₀) is stored into the data block 31, and a partial data parity a₀₀^{#} and a whole data parity A₀^{#} are stored in the parity block 33. The partial data parity a₀₀^{#} has a t-bit error correction capability for the portion of the data segment a₀₀, and the whole data parity A₀^{#} also has a t-bit error correction capability for the whole data segment A₀.

In a preferred embodiment of the present invention, the data segment and the parity can be stored sequentially in the format {a₀₀, a₀₁, A₀^{#}, a₀₀^{#}}, or {a₀₀, a₀₀^{#}, a₀₁, A₀^{#}}, or even all encoded parities can be recorded into another storage space without a connection with the content of the data segment; these formats are possible in addition to the storage format {a₀₀, a₀₁, a₀₀^{#}, A₀^{#}} shown in FIG. 3A. Take NAND flash as an example, the data segment is stored into a certain section of one page of a block in NAND flash, and all parities of the encoded data segments are specifically stored into one page of another block; or the data segments and all parities of the encoded data segments are stored into different storage media respectively, and the storage format is not limited to those disclosed in the present invention.

For actual practice, in regard to the decoding method of a portion of the data segment please refer to FIGS. 3B and 3C together, wherein the two are respectively the schematic view of a data segment storage format and the data process thereof in accordance with another preferred embodiment of the present invention. As shown by FIG. 3B, for every data segment, a storage medium is designed to allocate a data block 31 with 512 bits of fixed space and a parity block 33 with 16 bits of fixed space, in order to store the content of the data segments and the content of the parity respectively, Therein the parity block 33 is further separated into a data flow control flag block 35, a partial data parity block 37, and a whole data parity block 39. The data flow control flag block 35 is for storing the data flow control flag needed for encoding/decoding the data segments, the size of the data flow control flag block 35 may be adjusted based on requirement, in one embodiment, the data flow control flag block 35 takes up 3 bits; the partial data parity block 37 is for storing partial data parity a₀₀^{#}; the whole data parity block 39 is for storing a parity, wherein the parity is generated by the data flow control flag stored in the data flow control flag block 35 and the data stored in the data segment A₀.

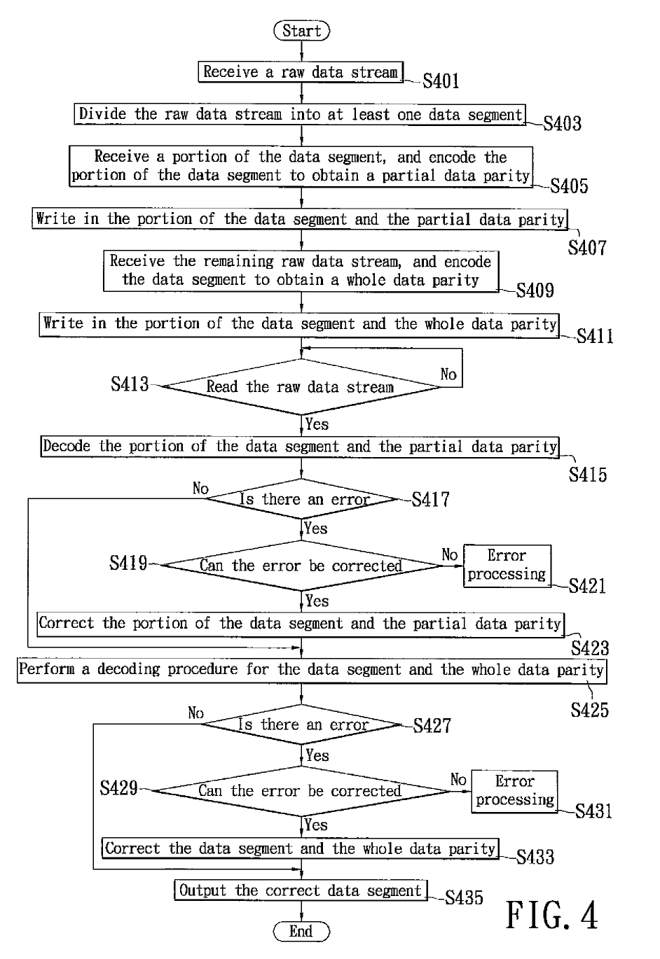

In the decoding process, as shown by FIG. 3C, the storage medium would provide another data block 31 and parity block 33 with the same format and space allocation (i.e. such as a page storage) in order to decode the portion of the data segment a₀₀ of FIG. 3A. In other words, the storage medium would provide another storage space with the same format and space allocation as the data segment. Therein, the decoding process entails filling the first 259 bits of the data block 31 of FIG. 3B with 0s; in other words, fill the front half of the storage space with 0s; wherein the first 256 bits of zero is filled to replace the space taken up by the portion of the data segment a₀₁, due to the fact it is the portion of the data parity a₀₀ that is to be checked and so a₀₁ is not desired at this point; the last 3 bits of 0s is filled to replace the space taken up by the data flow control flag block 35, which is also not needed. Next, after in the first 259 bits with 0s, the remaining 256 bits of space (i.e. second half of data block 31 and data flow control flag block 35, or also known as the latter half of the storage space) are filled with the portion of the data segment a₀₀, furthermore the partial data parity a₀₀^{#} is stored in to the whole data parity block 39 of the new page storage due to the fact that only data segment a₀₀ is being checked, so that now with only the relevant content, the partial data parity a₀₀^{#} can be used to correct the 515 bits content of the data segment that is formed by 0s and a₀₀. Referring to FIG. 4 for a flow chart of an error correction method in accordance with the present invention, and please also refer in conjunction to FIGS. 2 and 3A for its related circuit and data processing, a preferred embodiment is used for illustrating the way of processing a single data segment of the present invention, wherein the single data segment as the sole data segment can be considered as “the whole data segment”, “the whole data”, or “the data segment”, which are all accurate description of the single data segment. In FIG. 4, the error correction method comprises the following steps:

A raw data stream stored in a storage medium is received (Step S401). When an encode circuit defines the received data stream of a specific length, the encode circuit starts encoding the data stream, so that in the process of receiving a raw data stream, the raw data stream is divided sequentially into at least one data segment for the processing (Step S403). Each data segment has the same length (k-bit), and any subsequent data segment of the preferred embodiment uses a data segment A₀ (a.k.a. whole data segment A₀) as an example for the method steps. For the first half of the data segment A₀, the encode circuit as shown in FIG. 2 encodes a portion of the data segment a₀₀ to obtain a partial data parity a₀₀^{#} (Step S405), and a format as shown in FIG. 3 is used for storing the portion of the data segment a₀₀ and the partial data parity a₀₀^{#} into a storage medium (Step S407).

The remaining data segment a₀₁ is received. When all data of the data segment A₀ are received, the data segment A₀ is encoded to obtain a whole data parity A₀^{#} (Step S409), and then the format as shown in FIG. 3 (i.e. the format of {a₀₀,a₀₁,A₀^{#},a₀₀^{#}}) is used for storing the remaining data segment a₀₁ and the whole data parity A₀^{#} into the storage medium (Step S411), so as to complete the encoding procedure of a single data segment (i.e. the encoding of data segment A₀ is complete and A₀ now has associated parities). Of course, Steps S405 to S411 are carried out repeatedly for processing other data segments Aᵢ.

Furthermore, the storage medium will determine whether or not to receive an instruction of the received raw data stream (i.e. whether or not to read the raw data stream) (Step S413); if yes, then the content of the partial data parity a₀₀^{#} is read from the storage medium, and the partial data parity a₀₀^{#} is used for performing a decoding procedure for the data segment a₀₀ and the partial data parity a₀₀^{#} (Step S415). In the decoding process, a step is carried out to determine whether or not there is an error (Step S417). If there is no error, then the whole data parity A₀^{#} will be used for performing the decoding procedure for the data segment A₀ and the whole data parity A₀^{#} (Step S425), or else the partial data parity a₀₀^{#} will determine whether or not an error bit can be corrected (Step S419). If the number of error bits exceeds the error correction capability, then an error processing signal will be issued to inform users about the damage condition of the currently read data (Step S421). If the number of error bits has not exceeded the error correction capability, then the error bits in the data segment a₀₀ and the partial data parity a₀₀^{#} will be corrected (Step S423).

The whole data parity A₀^{#} is used continuously for performing the decoding procedure for the data segment A₀ and the whole data parity A₀^{#} (Step S425). In fact, at this time the content of the data segment a₀₀ in the data segment A₀ is correct (due to the fact that in order to reach step S425, there will have to be no error with a₀₀ to begin with or if the error in a₀₀ is corrected), and thus step of S425 is a process intended for further checking whether or not there is an error in the contents of the data segment a₀₁ and the whole data parity A₀^{#} in next step. In the decoding process, a step is performed to determine whether or not there is an error (Step S427). If there is no error, then the correct data segment A₀ will be outputted (Step S435), or else the step will further determine whether or not the error bits can be corrected (Step S429). If the number of error bits exceeds the error correction capability, then an error processing signal will be issued to inform users about the damage condition of the currently read data (Step S431), or else the error bits in the data segment A₀ (to be more precise, it would be the error bits from a₀₁ part of the data segment A₀) and the whole data parity A₀^{#} will be corrected (Step S433), so as to complete the decoding procedure of a single data segment.

Of course, Steps S415 to S433 are carried out repeatedly for processing other data segments Aᵢ. Finally, the corrected data segments A₀, A₁, . . . , A_{N} are combined into the raw data stream for the output.

In another preferred embodiment of the present invention, the whole data parity A₀^{#} is used to perform an error correction procedure for the whole data segment A₀ and the whole data parity A₀^{#} after the Step S413. If there is an error, then the Step S415 will be executed, or else each data segment Aᵢ will be combined for the output.

In another preferred embodiment of the present invention, Steps S425 to S433 are carried out after the Step S413, and the whole data parity A₀^{#} can be used for carrying out the processes of decoding and correcting the whole data segment A₀ and the whole data parity A₀^{#} and then Steps S415 to S433 are carried out to combine each data segment Aᵢ for the output.

For one preferred implementation, it is considered that since it is rare for error to take place, it would be time saving to decode the whole data first. Only when it is found that there is an uncorrectable error in the whole data segment A₀ and whole data parity A₀^{#}, then shall the aforementioned partial data decoding process be performed.

In a preferred embodiment of the present invention, each data segment can be divided into a plurality of partial data segment for encoding as a plurality of error correction codes to increase the error correction capability by multiple times. More specifically, if the data segment A₀ is divided into three portions of data segments a₀₀, a₀₁, a₀₂, there would be two partial data parities a₀₀^{#}, a₀₁^{#} and one whole data parity A₀^{#} after encoding process, wherein the partial data parity a₀₀^{#} has t-bit error correction capability for the data segment a₀₀ and the partial data parity a₀₀^{#}, and the partial data parity a₀₁^{#} has t-bit error correction capability for the data segment a₀₀˜a₀₁ and the partial data parity a₀₁^{#}, and so forth. This technical feature is distinctly different from prior art, wherein there would be only one parity for each data segment and the error correction capability is limited to the error correction code of the hardware design (i.e. a₀₀^{#} corrects a₀₀ and a₀₁^{#} corrects a₀₁). However, in the present invention, due to the fact that there are two partial data parities and one whole data parity, the error correction capability is enhanced three times for the whole data segment, under the condition that each portion of data contains no more than t error bits.

To achieve the effect of dividing the data segment A₀ into a plurality of portions for the encoding process, the hardware circuit adds a buffer area as the auxiliary shift registers b₀′, b₁′, . . . , bₙ₋ₖ₋₁′ as shown in FIG. 2, wherein the buffer area provides a plurality of auxiliary shift registers, and switches SW are provided for controlling each partial data parity of different portions of the data segments to be temporarily stored for future decoding. The present invention can improve the error correction capability by several times by simply adding the auxiliary shift registers buffer which is of low cost.

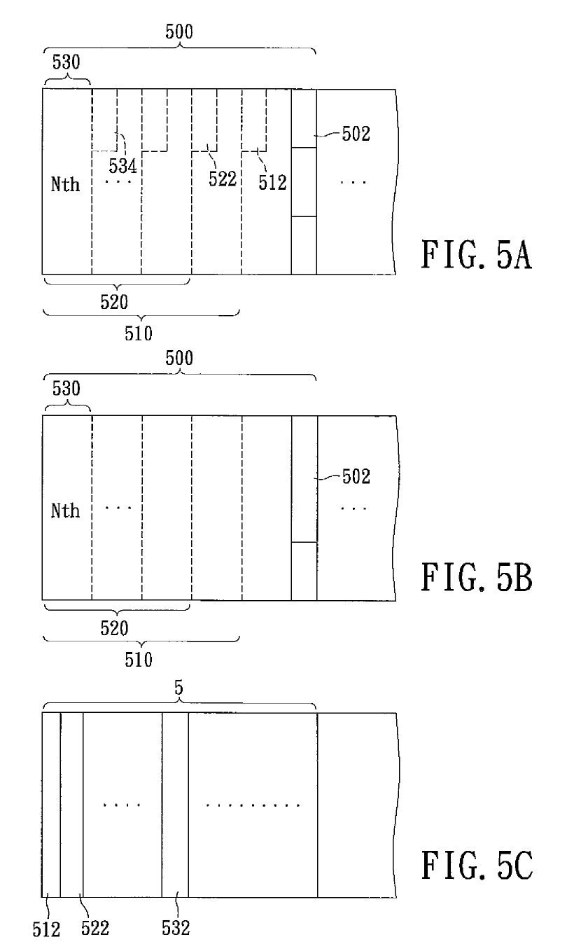

Please reference FIG. 5A for another schematic view of a data segment storage format in accordance with a preferred embodiment of the present invention, and view in conjunction with FIG. 2, 3A˜3C for the related encoding circuit and its operation. As shown in FIG. 5A, the data stream is divided into a plurality of data segments 500 with an equal length. Each segment 500 has a first portion of the data segment 510, a second portion of the data segment 520, . . . , a Nth portion of the data segment 530, wherein the second portion of the data segment 520 is partial of the first portion of the data segment 510, and so forth. After the encoding process, the whole data parity 502 of the data segments 500, the first data parity 512 of the first portion of the data segment 510, . . . , the Nth data parity 532 of the Nth portion of the data segment 530 are produced. Those data parities are stored in the same page. Or, furthermore refer to FIG. 5B, 5C, the whole data parity 502 is still recorded with the content of the data segment. And all partial parities of the encoded data segments are specifically stored into another page as shown in FIG. 5C.

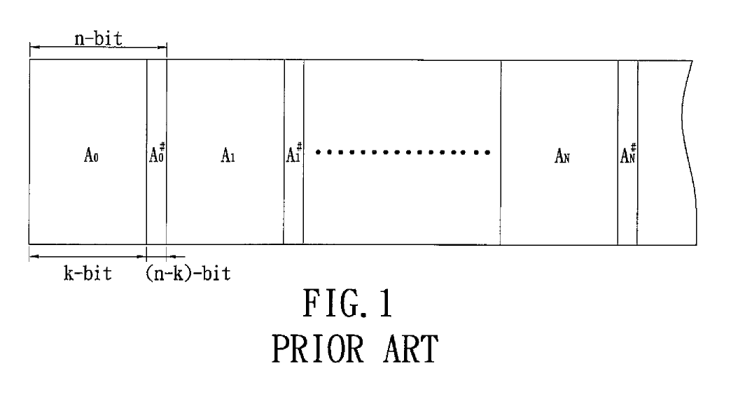

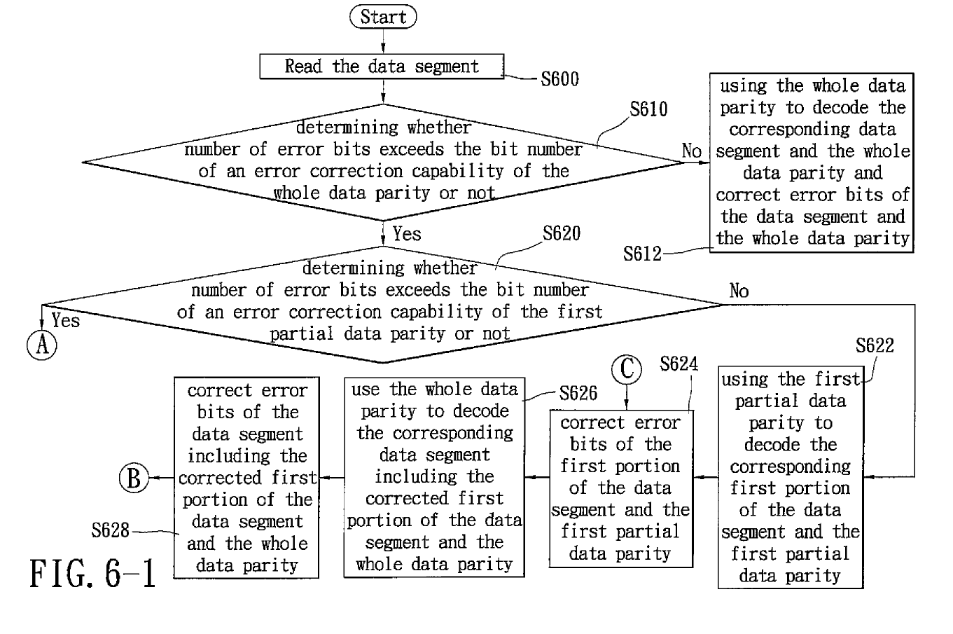

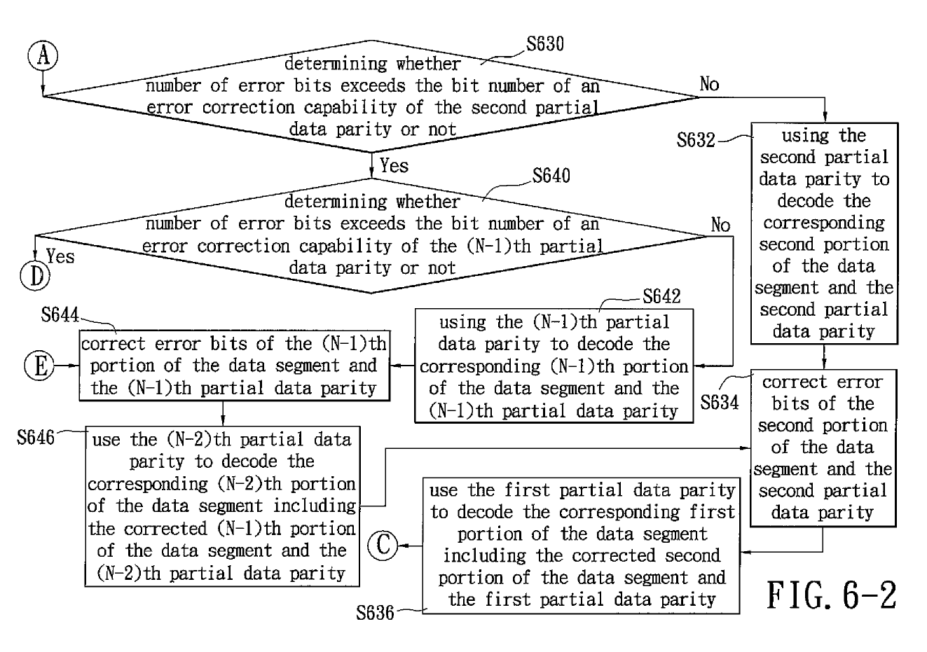

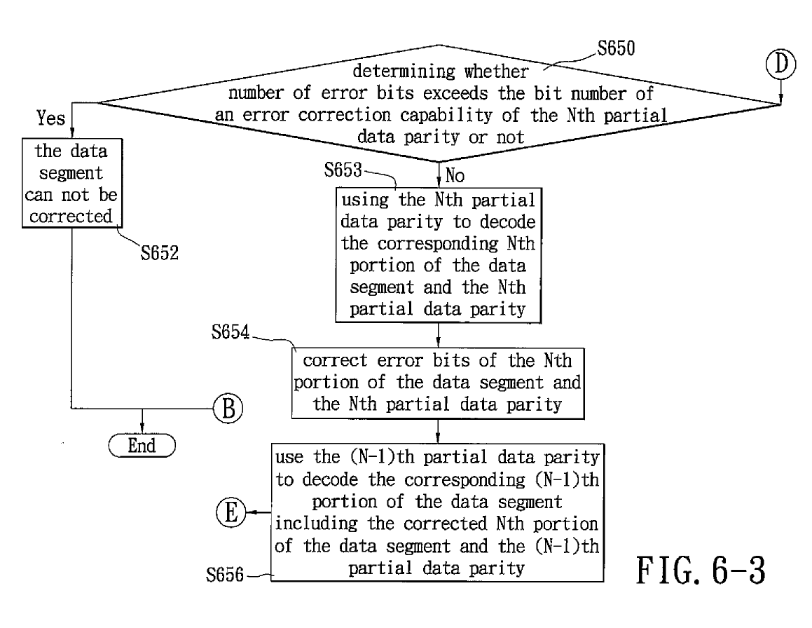

Finally, referring to FIG. 6-1˜6-3 for flow charts of an error correction method in accordance with the present invention which is based on the storage format of the FIG. 5A˜5C, and please also refer in conjunction with FIGS. 2 and 5A˜5C for its related circuit and data processing, a preferred embodiment is used for illustrating the way of processing a single data segment of the present invention, wherein the single data segment as the sole data segment can be considered as “the whole data segment”, “the whole data”, or “the data segment”, which are all accurate description of the single data segment. In FIG. 6-1˜6-3, the error correction method comprises the following steps:

Read the data segment (Step S600) and determine whether number of error bits exceeds the bit number of an error correction capability of the whole data parity 502 or not (Step S610). If no, the encode circuit uses the whole data parity 502 to decode the corresponding data segment 500 and the whole data parity 502 and to correct error bits of the data segment 500 and the whole data parity 502 (Step S612). Or, determine whether number of error bits exceeds the bit number of an error correction capability of the first partial data parity 512 or not (Step S620). If no, the encode circuit uses the first partial data parity 512 to decode the corresponding first portion of the data segment 510 and the first partial data parity 512 (Step S622). Then, correct error bits of the first portion of the data segment 510 and the first partial data parity 512 (Step S624). And use the whole data parity 502 to decode the corresponding data segment 500 including the corrected first portion of the data segment 510 and the whole data parity 502 (Step S626), then, to correct error bits of the data segment 500 including the corrected first portion of the data segment 510 and the whole data parity 502 (Step S628).

If number of error bits exceeds the bit number of an error correction capability of the first partial data parity 512, determine whether number of error bits exceeds the bit number of an error correction capability of the second partial data parity 522 or not (Step S630). If no, use the second partial data parity 522 to decode the corresponding second portion of the data segment 520 and the second partial data parity 522 (Step S632). Then, the encode circuit corrects error bits of the contents of the data segment 500 based on above operations.

Similarly, determine which segment has error bits and correct them according to above operations until the data segment 500 is recovered. However, if the number of error bits exceeds the bit number of an error correction capability of the Nₜₕ partial data parity 532, then an error processing signal will be issued to inform users about the damage condition of the currently read data (Step S652).

The error correction method of the present invention is disclosed by the aforementioned preferred embodiments, and is disclosed by the method which divides a data segment into multiple data portion for error correction code encoding, and then produces partial data parities and a whole data parity after encoding each portion of the data segments and the whole data segment, and the partial data parities and the whole data parity are used for decoding and correcting errors of the corresponding data segment. Each of the parity has the same error correction capability for the corresponding data, and thus the present invention can achieve the purpose of improving the error correction capability by several times without increasing much of the complexity of hardware or software.

Although the present invention has been described with reference to the preferred embodiments thereof, it will be understood that the present invention is not limited to the details thereof. Various substitutions and modifications have been suggested in the foregoing description, and others will occur to those of ordinary skill in the art. Therefore, all such substitutions and modifications are intended to be embraced within the scope of the present invention as defined in the appended claims.

What is claimed is:

1. An error correction method, applied in an electronic system having a storage medium for accessing a data stream, wherein the data stream being divided into a plurality of data segments with an equal length, the improvement comprising each the data segment having a first portion of the data segment at least; encoding the data segment and the corresponding first portion of the data segment to produce a whole data parity and a first partial data parity respectively when performing an encoding procedure; and performing a decoding procedure comprising the steps of: using the first partial data parity to decode the first portion of the data segment and the first partial data parity for correcting error bits in the first portion of the data segment and the first partial data parity; and using the whole data parity to decode the corresponding data segment and the whole data parity for correcting error bits of the data segment and the whole data parity.

2. The error correction method of claim 1, wherein each of the first portion of the data segment further has a second portion of data segment which is encoded to produce a second partial data parity when performing the encoding procedure and while performing the decoding procedure using the second partial data parity to decode the second portion of the data segment and the second partial data parity for correcting error bits in the second portion of the data segment and the second partial data parity.

3. The error correction method of claim 2, wherein the decoding procedure further comprises the steps of:
using the second partial data parity to decode the second portion of the data segment and the second partial data parity for correcting error bits in the second portion of the data segment and the second partial data parity;
using the first partial data parity to decode the first portion of the data segment including the corrected second portion of the data segment and the first partial data parity for correcting error bits in the first portion of the data segment and the first partial data parity; and
using the whole data parity to decode the corresponding data segment including the corrected the first portion of the data segment and the whole data parity for correcting error bits of the data segment and the whole data parity.

4. The error correction method of claim 1, wherein an error correction capability for the data segment is directly proportional to the number of the partial data parities contained in the data segment.

5. The error correction method of claim 1, wherein the partial data parities can be stored in different page from the corresponding data segment.

6. The error correction method of claim 1, wherein the step of using the first partial data parity to decode the first portion of the data segment and the first partial data parity includes the following steps:
providing another storage space with the same format and space allocation as the data segment;
storing first portion of the data segment within the storage space;
filling the remaining the storage space with a plurality of zeros; and
using the corresponding first partial data parity to decode the content within the storage space.

7. The error correction method of claim 6, wherein the plurality of zeros in the storage space fills the front half of the storage space, and the first portion of the data segment is stored in the latter half of the storage space.

8. The error correction method of claim 3, wherein the step of using the second partial data parity to decode the second portion of the data segment and the second partial data parity includes the following steps: providing another storage space with the same format and space allocation as the data segment, storing second portion of the data segment within the storage space, filling the remaining the storage space with a plurality of zeros, and using the corresponding second partial data parity to decode the content within the storage space; and the step of using the first partial data parity to decode the first portion of the data segment and the first partial data parity includes the following steps: providing another storage space with the same format and space allocation as the data segment, storing first portion of the data segment within the storage space, filling the remaining the storage space with a plurality of zeros, and using the corresponding first partial data parity to decode the content within the storage space.

9. An error correction method, applied in a storage medium for accessing a data stream, and the data stream being divided into a plurality of data segments with an equal length, and the method comprising the steps of:
performing an encoding procedure on each the data segment having a first portion of the data segment at least, comprising the steps of:
encoding the first portion of the data segments to produce a first partial data parity; and
encoding the data segments to produce a whole data parity; and
performing a decoding procedure on each the data segment, comprising the steps of:
determining whether number of error bits exceeds the bit number of an error correction capability of the whole data parity;
correcting error bits of the data segment and the whole data parity when the number of error bits not exceeds the error correction capability; and
using the first partial data parity to decode the corresponding first portion of the data segment and the first partial data parity when the number of error bits exceeds the error correction capability;
correcting error bits of the first portion of the data segment and the first partial data parity;
using the whole data parity to decode the corresponding data segment including the corrected first portion of the data segment and the whole data parity; and
correcting error bits of the data segment and the whole partial data parity.

10. The error correction method of claim 9, wherein the step of using the first partial data parity to decode the corresponding first portion of the data segment and the first partial data parity includes the following steps:
providing another storage space with the same format and space allocation as the data segment;
storing the first portion of the data segment within the storage space;
filling the remaining the storage space with a plurality of zeros; and
using the first partial data parity to decode the content within the storage space.

11. The error correction method of claim 10, wherein the plurality of zeros in the storage space fills the front half of the storage space, and the first portion of the data segment is stored in the latter half of the storage space.

12. The error correction method of claim 9, wherein each of the first portion of the data segment further has a second portion of data segment which is encoded to produce a second partial data parity when performing the encoding procedure and performing the decoding procedure using the second partial data parity to decode the second portion of the data segment and the second partial data parity for correcting error bits in the second portion of the data segment and the second partial data parity.

13. The error correction method of claim 12, wherein before the step of using the first partial data parity to decode the corresponding first portion of the data segment and the first partial data parity further comprises the steps of:
determining whether number of error bits exceeds the bit number of an error correction capability of the first data parity;
executing the step of using the first partial data parity to decode the corresponding first portion of the data segment and the first partial data parity when the number of error bits not exceeds the error correction capability; and
using the second partial data parity to decode the corresponding second portion of the data segment and the second partial data parity when the number of error bits exceeds the error correction capability;
correcting error bits of the second portion of the data segment and the second partial data parity;
using the first partial data parity to decode the corresponding first portion of the data segment including the corrected second portion of the data segment and the first partial data parity;
correcting error bits of the first portion of the data segment and the first partial data parity;
using the whole data parity to decode the corresponding data segment including the corrected first portion of the data segment and the whole data parity; and
correcting error bits of the data segment and the whole partial data parity.

14. The error correction method of claim 13, wherein the step of using the second partial data parity to decode the second portion of the data segment and the second partial data parity includes the following steps: providing another storage space with the same format and space allocation as the data segment, storing second portion of the data segment within the storage space, filling the remaining the storage space with a plurality of zeros, and using the corresponding second partial data parity to decode the content within the storage space; and the step of using the first partial data parity to decode the first portion of the data segment and the first partial data parity includes the following steps: providing another storage space with the same format and space allocation as the data segment, storing first portion of the data segment within the storage space, filling the remaining the storage space with a plurality of zeros, and using the corresponding first partial data parity to decode the content within the storage space.

15. The error correction method of claim 9, wherein the partial data parities can be stored in different page from the corresponding data segment.

16. The error correction method of claim 9, wherein the error correction capability for the data segment is directly proportional to the number of the partial data parities contained in the data segment.

17. The error correction method of claim 9, wherein the partial data parity can be stored in the same page with the corresponding data segment and the whole data parity.

18. An error correction circuit, applicable in a storage medium for accessing a data stream, and the error correction circuit comprising:
a plurality of shift registers, for receiving the data stream to produce a whole data parity; and
a plurality of auxiliary shift registers, for receiving a portion of the data stream to produce a partial data parity,
whereby the storage medium uses the whole data parity and the partial data parity to correct the data stream and the portion of the data stream respectively.

19. An error correction circuit of claim 18, further comprising:
a plurality of XOR gates, and the XOR gates are installed alternately with the shift registers.

20. An error correction circuit of claim 18, further comprising:
a plurality of switches, coupled between the shift registers and the auxiliary shift registers,
wherein when the switches are closed, the auxiliary shift registers receives the portion of the data stream and produce the partial data parity; and when the switches are open, the shift registers receives the data stream and produce the whole data parity.
